(19) United States
(12) Patent Application Publication
(10) Pub. No.: US 2006/0145262 A1
(43) Pub. Date: Jul. 6, 2006

(54) Tunable ESD device for multi-power application

(75) Inventors: Chien-Chih Lu, Taipei City (TW); Len-Yi Lu, Hsinchu City (TW); Kuo-Shih Teng, Hsinchu City (TW); Kun-Huan Shih, Nantou County (TW)

Correspondence Address: BIRCH STEWART KOLASCH & BIRCH, PO BOX 747, FALLS CHURCH, VA, 22040-0747, US

(73) Assignee: Winbond Electronics Corp.

(21) Appl. No.: 11/177,568

(22) Filed: Jul. 11, 2005

(30) Foreign Application Priority Data
Jan. 5, 2005 (TW) 94100234

(51) Int. Cl. H01L 23/62

(52) U.S. Cl. 257/356

(57) ABSTRACT

A tunable ESD device for multi-power application. The ESD device comprises a substrate, at least one first well of a first conductivity, and a doped region of a second conductivity. The first wells of the first conductivity are located in the substrate. The doped region of the second conductivity substantially surrounds the first wells of the first conductivity. The doped region of the second conductivity is a drain region of a MOSFET and the distance thereto from the first wells of the first conductivity is between 0.01 μm and 1.5 μm.

### BACKGROUND

The invention relates to electrostatic discharge (ESD) protection and, in particular, to an ESD device for multi-power application.

For high voltage applications, such as TFT-LCD or STN-LCD driver integrated circuits (ICs), multiple power supplies are usually required for circuit operation. In order to protect the entire chip from ESD damage, efficient power clamping ESD cells for different power pins and efficient ESD cells for other pad types are critical to the chip design.

FIG. 1 shows a layout of a conventional high voltage device, a lateral double diffused metal oxide semiconductor (LDMOS). The high voltage device must be large enough to act as an ESD device, whereby a large current can be discharged in a short time. Thus, the layout with multiple fingers and high channel width is typically required. FIG. 2 shows a cross section of the high voltage device taken along the dashed line A-A′ in FIG. 1. Each drain region 202 is disposed in an N-type well region 204. A distance D₀ from the drain region 202 to the N-type well region 204 is required to enhance junction breakdown voltage.

A high voltage device alone, LDMOS for example, without additional ESD devices is typically not a good candidate for ESD cells, since an LDMOS is often designed such that the trigger voltage thereof is its N-well 202 to P-well 203 breakdown voltage at drain junction, typically more than 50V. Such a trigger voltage significantly degrades the response time of an ESD cell. As well, the trigger voltage of the LDMOS alone, as an ESD device, is the same as the trigger voltage of LDMOS devices in the internal circuit, so the ESD device could not prevent the internal circuit from ESD damage. Finally, the trigger voltage of the LDMOS cannot be adjusted to protect power pins with different supply voltages.

In order to reduce response time of the ESD cell, the ideal trigger voltage must exceed the corresponding supply voltage and be lower than the internal gate oxide and junction breakdown voltage, low enough to reduce response time.

In addition, several types of ESD devices with different trigger voltages exceeding corresponding supply voltages are required for multi-power integrated circuits. Such design is more complicated. An ESD device with a tunable trigger voltage enables whole chip ESD protection. Preferably, the trigger voltage of the ESD device is lower than a normal LDMOS.

### SUMMARY

Embodiments of the invention provide an ESD device with a tunable trigger voltage. The trigger voltage is tunable to exceed the corresponding supply voltage, while being lower than the internal gate oxide and junction breakdown voltage and low enough to reduce response time for ESD protection. Embodiments of the invention are applicable to multi-power integrated circuits. An ESD device is applicable to various power supply voltages by adjustment of the distance from a drain region to a well region, where a breakdown event occurs. The design is thus significantly simplified.

Embodiments of the invention provide a tunable ESD device. The ESD device comprises a substrate, at least one first well region of a first conductivity, and a doped region of a second conductivity. The first wells of the first conductivity are located in the substrate. The doped region of the second conductivity substantially surrounds the first wells of the first conductivity. The doped region of the second conductivity is a drain region of a MOSFET and the distance thereto from the first wells of the first conductivity is between 0.01 μm and 1.5 μm.

### DESCRIPTION OF THE DRAWINGS

FIG. 1 shows a layout of a conventional LDMOS transistor.

FIG. 2 is a cross section of the conventional LDMOS transistor shown in FIG. 1.

FIG. 3 shows a layout of a LDMOS transistor according to a first embodiment of the invention.

FIG. 4 is a cross section of the LDMOS structure along line A-A′ of FIG. 3.

FIG. 5 shows experimental data of breakdown voltage versus distance L from the N-type drain region to the P-type first well region of a tunable ESD device.

FIG. 6 shows layout of the LDMOS transistor according to the second embodiment of the invention.

FIG. 7 is a cross section of the LDMOS structure along line A-A′ of FIG. 6.

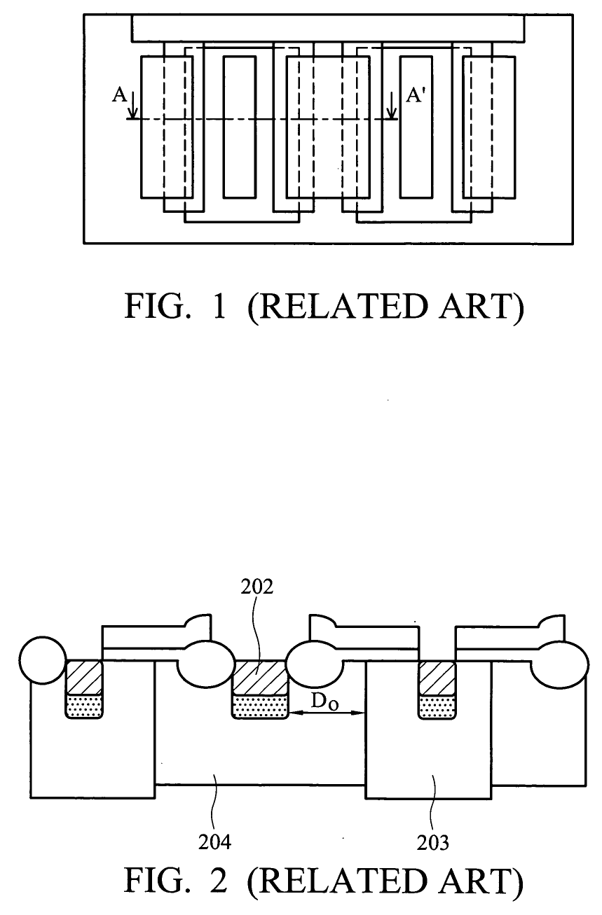

### DETAILED DESCRIPTION

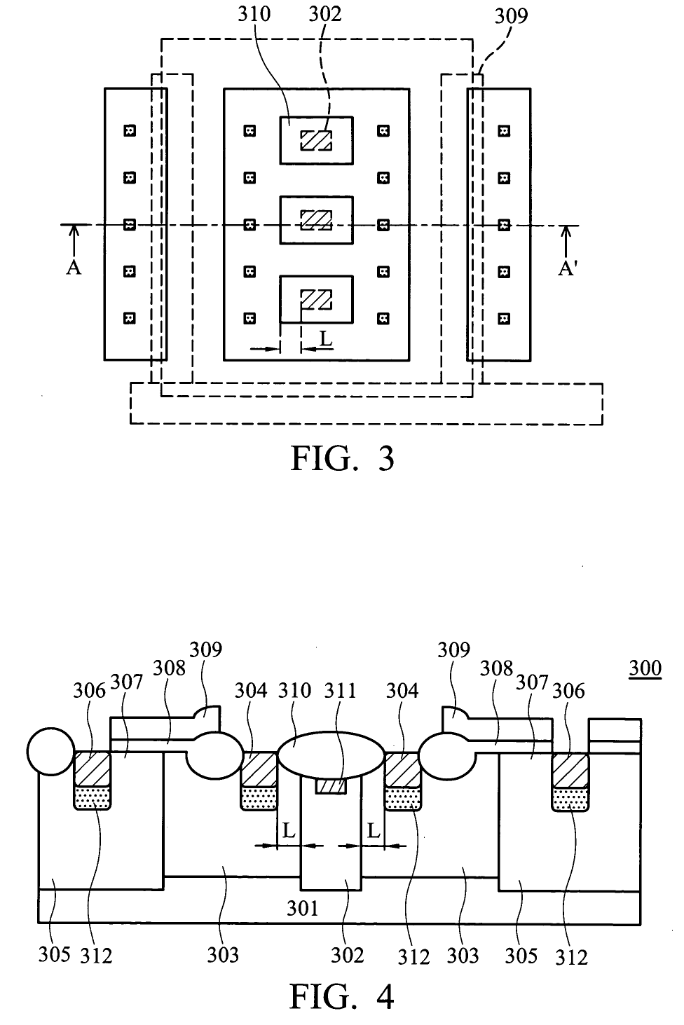

FIGS. 3 and 4 are schematic diagrams of a LDMOS structure according to a first embodiment of the invention. FIG. 3 shows a layout of a LDMOS structure while FIG. 4 is a cross section of the LDMOS structure along line A-A′ of FIG. 3. N-type LDMOS transistors are used here as an example. The scope of the invention, however, is not limited thereto.

As shown in FIGS. 3 and 4, the LDMOS transistor 300 comprises a substrate 301, at least one P-type first well region 302, an N-type second well region 303, an N-type drain region 304, two P-type third well regions 305, two N-type source regions 306, two channel regions 307, a first dielectric layer 308 and a gate 309. The P-type first well region 302 is located in the substrate 301. The N-type drain regions 304, while around the P-type first well regions 302, do not necessarily enclose them. In other words, the N-type drain regions 304 are located at least on two sides of the P-type first well regions 302 respectively. The N-type source regions 306 are located in the P-type third well regions 305. The channel regions 307 are respectively located between the N-type source regions 306 and the N-type second well regions 303 and connected to the N-type source regions 306. The first dielectric layer 308 is located on the substrate 301 and disposed between the N-type drain regions 304 and the source regions 306. The first dielectric layer 308 has a first part adjacent to the source regions 306 and a second part adjacent to the drain region 304. The first and second parts of the first dielectric layer 308 are of different thicknesses. Preferably, the second part of the first dielectric layer 308 is thicker than the first part. The gate 309 is disposed on the first dielectric layer 308. The distance L from the N-type drain region 304 to the P-type first well region 302 is small enough that junction breakdown occurs at the junction between the N-type drain region 304 and the P-type first well region 302. Preferably, the distance L is between 0.01 μm and 1.5 μm.

As shown in FIGS. 3 and 4, the N-type second well regions 303, while around the P-type first well regions 302, do not necessarily enclose them. In other words, the N-type second well regions 303 are located at least on two sides of the P-type first well regions 302. The N-type second well regions 303 cover the N-type drain regions 304 and the second part of the first dielectric layer 308. The P-type third well regions 305 are located on two sides of the N-type second well regions 303 respectively. The P-type third well regions cover the N-type source regions 306 and the first dielectric layer 308. The N-type channel regions 307 are respectively located in the P-type third well regions 305.

In addition, as shown in FIG. 4, the LDMOS transistor 300 further comprises a mask material layer 310 and a P-type implant region 311. The mask material layer 310 is located on the P-type first well regions 302. The mask material layer 310 can be a field oxide, an normal oxide formed during gate oxide formation, or a poly-silicon layer. The P-type implant region 311 is located between the mask material layer 310 and the P-type first well regions 302. Furthermore, the material of the mask material layer 310 even can be a photo resist in process, it will be stripped after formation of a predetermined distance between the p-type first well region 302 and the N-type drain region 304.

Moreover, the LDMOS transistor 300 further comprises N-type lightly doped (LDD) regions 312, respectively located under the N-type source/drain regions. The disclosed embodiment is referred to as a 2-finger LDMOS transistor. The invention, however is not limited thereto. An LDMOS transistor with a multi-finger structure is also applicable.

When the drain regions 304 of the ESD cell are subjected to a high voltage pulse (ESD), an boundary of a depletion region of N-well/P-well junction at the drain side moves toward the drain regions 304. Thus, a shorter spacing L results in a lower breakdown voltage at the drain junction and a smaller trigger voltage of the ESD cell. As a result, the trigger voltage can be adjusted by tuning the spacing L. The ESD device is triggered when device breakdown occurs, whereby a high current is discharged to ground fast enough to protect internal devices from damage during an ESD event.

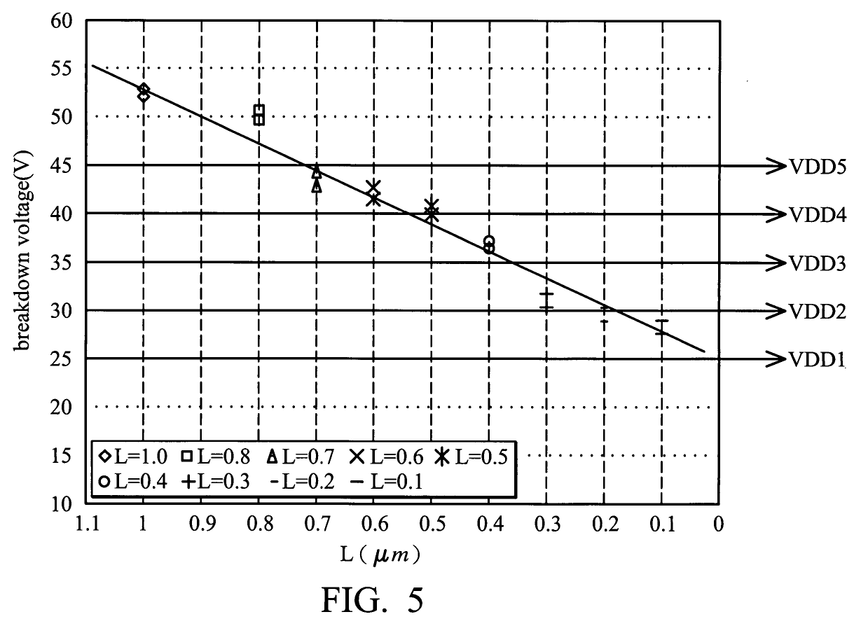

FIG. 5 shows experimental data of a breakdown voltage versus the distance L from the N-type drain region 304 to the P-type first well region 302 of a tunable ESD device. It is found that a shorter distance L results in a lower device breakdown voltage. To be an effective ESD cell, a maximum trigger voltage level is determined by a gate oxide breakdown or device junction breakdown and a minimum trigger voltage level is determined by a breakdown voltage, approximately 25V, at L=Opm. In this embodiment, the tunable trigger voltage ranges from 25 to 50V. In order to provide an efficient ESD device, a suitable trigger voltage is required for each supply voltage level VDD. For example, for VDD=20V, an ESD cell with a trigger voltage of 35V is better than 40V. The following Table 1 is a design guideline for any product with multiple power supply voltages.

TABLE 1

| | | Distance L from the |
|---|---|---|
| | | N-type drain regions 304 |
| | Trigger | to the P-type first well |
| VDD voltage | voltage (V) | regions 302 (μm) |
| VDD1 | 25˜30 | 0.1˜0.2 |
| VDD2 | 30˜35 | 0.3 |
| VDD3 | 35˜40 | 0.4˜0.5 |
| VDD4 | 40˜45 | 0.6˜0.7 |
| VDD5 | 45˜50 | 0.8˜0.9 |

As shown in FIG. 3, the P-type first well regions 302 are surrounded by the N-type drain regions 304. Since the drain regions 304 on two sides of the P-type first well regions 302 are still connected, normalizing their potential, the drain regions 304 on two sides of the P-type first well regions 302 simultaneously respond to an ESD event when they are subjected to a large voltage pulse (ESD). Thus, ESD performance is improved by eliminating non-uniform turn-on.

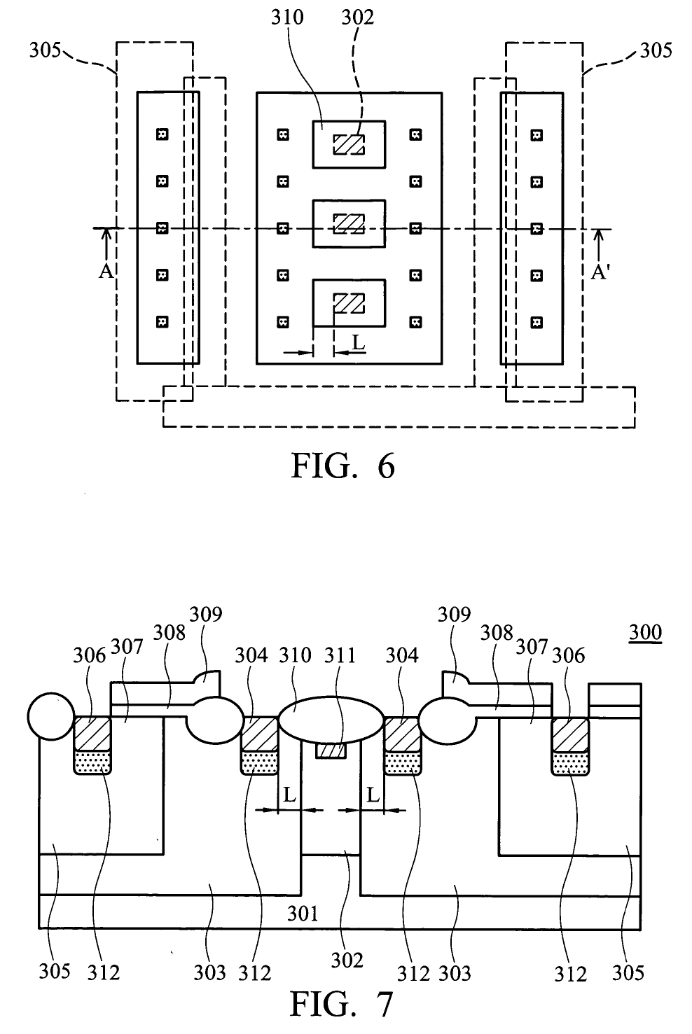

A second embodiment of the invention provides a variation of the disclosed LDMOS transistor. FIG. 6 is a layout of the LDMOS transistor according to the second embodiment of the invention. FIG. 7 is a cross section of the LDMOS structure along line A-A′ of FIG. 6. In the second embodiment, unlike the first, the N-type second well regions 303 cover not only the drain regions 304 and the second part of the first dielectric layer 308 but also the P-type third well regions 305. These second well regions are also called drift regions.

Embodiments of the invention provide an ESD device with a tunable trigger voltage. The trigger voltage is tunable to exceed the corresponding supply voltage, while being lower than the internal gate oxide and junction breakdown voltage and low enough to reduce response time for ESD protection.

While the invention has been described by way of example and in terms of preferred embodiment, it is to be understood that the invention is not limited thereto. To the contrary, it is intended to cover various modifications and the advantages would be apparent to those skilled in the art. Therefore, the scope of the appended claims should be accorded to the broadest interpretation so as to encompass all such modifications.

What is claimed is:

1. A tunable ESD device, comprising:
a substrate;
at least one first well region, located in the substrate, having a first conductivity; and
a doped region, surrounding the first well regions of the first conductivity, having a second conductivity;
wherein the doped region of the second conductivity is a drain region of a MOSFET and the distance thereto from the first wells of the first conductivity is between 0.01 μm and 1.5 μm.

2. The tunable ESD device as claimed in claim 1, further comprising:
two source regions of the second conductivity;
two channel regions of the second conductivity, each located between the source and drain regions of the second conductivity and connected to the source regions of the second conductivity;
a first dielectric layer, located between the source and drain regions of the second conductivity, on the substrate; and
a gate located on the first dielectric layer.

3. The tunable ESD device as claimed in claim 2, wherein the first dielectric layer has a first part next to the source regions and a second part, of different thickness than the first, next to the drain regions.

4. The tunable ESD device as claimed in claim 3, wherein the second part of the first dielectric layer is a field oxide.

5. The tunable ESD device as claimed in claim 2, further comprising a second well region of the second conductivity, covering the drain regions of the second conductivity and the second part of the first dielectric layer.

6. The tunable ESD device as claimed in claim 2, further comprising a third well region of the first conductivity, covering the source regions of the second conductivity and the first part of the first dielectric layer, comprising one of the channel regions of the second conductivity.

7. The tunable ESD device as claimed in claim 2, further comprising a mask material layer surrounded by the drain regions, on the first wells of the first conductivity.

8. The tunable ESD device as claimed in claim 6, further comprising an implant region of the first conductivity between the mask material layer and the first well regions of the first conductivity.

9. The tunable ESD device as claimed in claim 6, wherein the mask material layer is a field oxide, a normal oxide, or a poly-silicon layer.

10. The tunable ESD device as claimed in claim 2, further comprising a lightly doped region of the second conductivity under the source/drain regions of the second conductivity.
